(19) United States
(12) Patent Application Publication
(10) Pub. No.: US 2025/0156396 A1
(43) Pub. Date: May 15, 2025

(54) DATA INTEGRITY DETECTION

(71) Applicant: QUALCOMM Incorporated, San Diego, CA (US)

(72) Inventors: Richard SENIOR, San Diego, CA (US); Sundeep KUSHWAHA, Round Rock, TX (US); Scott Russell BAUER, Seattle, WA (US); Gurvinder Singh CHHABRA, San Diego, CA (US); Norris GENG, San Diego, CA (US); Christopher KOOB, Round Rock, TX (US); Sergei LARIN, Austin, TX (US); Vipin SALI, San Diego, CA (US); Murali SOMANCHY, San Marcos, CA (US); Aleksandr Sergeevich TARASIKOV, Berlin (DE)

(21) Appl. No.: 18/509,115

(22) Filed: Nov. 14, 2023

(51) Int. Cl. G06F 16/23; H03M 7/30

(52) U.S. Cl. CPC G06F 16/2365; G06F 11/167; H03M 7/60

(57) ABSTRACT

Aspects of the disclosure are directed to data integrity detection. In accordance with one aspect, an apparatus including a compressed data sector configured to store a compressed data; a meta data sector coupled to the compressed data sector, the meta data sector configured to indicate an invalid meta data index; and a compression/decompression engine coupled to the meta data sector, the compression/decompression engine configured to compress an original data to generate the compressed data and further configured to decompress the compressed data to generate a decompressed data.

### TECHNICAL FIELD

This disclosure relates generally to the field of information processing systems and, in particular, to data integrity detection for information processing systems.

### BACKGROUND

Many information processing systems include multiple processing engines, processors or processing cores for a variety of user application

s. An information processing system may include a central processing unit (CPU), a graphics processing unit (GPU), a digital signal processor (DSP), an image signal processor (ISP), a neural processing unit (NPU), etc., along with input/output interfaces, a hierarchy of memory units and associated interconnection databuses. The hierarchy of memory units may include a compressed memory unit where a compression/decompression engine is used to reduce storage requirements of data in main memory or cache memory by implementing data compression prior to storage and implementing data decompression after retrieval from storage. Since the compressed memory unit is vulnerable to security attacks, the information processing system may require a data integrity detection mechanism for real-time detection of buffer overflows due to a security attack.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the present disclosure provides data integrity detection for information processing systems. Accordingly, an apparatus for data integrity detection, the apparatus including a compressed data sector configured to store a compressed data; a meta data sector coupled to the compressed data sector, the meta data sector configured to indicate an invalid meta data index; and a compression/decompression engine coupled to the meta data sector, the compression/decompression engine configured to compress an original data to generate the compressed data and further configured to decompress the compressed data to generate a decompressed data.

In one example, the decompressed data is not the original data. In one example, the apparatus further includes a canary, wherein the canary is a designated memory location in the meta data sector, the canary configured to detect a memory buffer overflow due to a security attack or a programming error. In one example, the apparatus further includes a processor coupled to compression/decompression engine, the processor configured to detect a fault condition. In one example, the apparatus further includes a fault protection circuit located in a core processor of the processor, the fault protection circuit configured to detect the fault condition. In one example, the fault condition is a hardware exception.

Another aspect of the disclosure provides a method for implementing data integrity detection, the method including inserting a canary into a meta data associated with a data in a compressed data sector; executing the software code with an inserted canary into the meta data; monitoring for a hardware exception due to a canary memory access; and declaring a real-time fault condition if the hardware exception is due to the canary memory access being detected during the executing the software code.

In one example, the method further includes executing a recovery procedure from the real-time fault condition. In one example, the method further includes retrieving an original data from the main memory and sending the original data to a compression module of a compression/decompression engine. In one example, the method further includes executing data compression of the original data to generate a compressed data of a compressed size of M bits. In one example, the original data has an original size of N bits such that N is greater than M.

In one example, the method further includes storing the compressed data in a compressed data sector of the main memory using the meta data index. In one example, the method further includes generating the inserted canary in the compressed data sector. In one example, the inserted canary is stored after the compressed data sector is dynamically allocated.

In one example, the compressed data sector is dynamically allocated on a stack memory. In one example, the compressed data sector is dynamically allocated on a heap memory. In one example, the meta data index includes an invalid value. In one example, the meta data index is outside a valid meta data index range. In one example, the canary includes a canary virtual address. In one example, the canary uses an address label which points outside a valid meta data index range for a compressed data area. In one example, the inserted canary is inserted at a location of a previously allocated memory area. In one example, the meta data index includes a valid meta data index range for determining a memory buffer overflow.

Another aspect of the disclosure provides an apparatus for data integrity detection, the apparatus including means for inserting a canary into a meta data associated with a data in a compressed data sector; means for executing the software code with an inserted canary into the meta data; means for monitoring for a hardware exception due to a canary memory access; and means for declaring a real-time fault condition if the hardware exception is due to the canary memory access being detected during the executing the software code.

In one example, the apparatus further includes means for executing a recovery procedure from the real-time fault condition. In one example, the apparatus further includes means for storing a compressed data in a compressed data sector of the main memory using the meta data index. In one example, the inserted canary is stored after the compressed data sector is dynamically allocated. In one example, the meta data index includes an invalid value, or wherein the meta data index is outside a valid meta data index range. In one example, the inserted canary is inserted at a location of a previously allocated memory area.

Another aspect of the disclosure provides a non-transitory computer-readable medium storing computer executable code, operable on a device including at least one processor and at least one memory coupled to the at least one processor, wherein the at least one processor is configured to implement data integrity detection, the computer executable code including instructions for causing a computer to insert a canary into a meta data associated with a data in a compressed data sector; instructions for causing the computer to execute the software code with an inserted canary into the meta data; instructions for causing the computer to monitor for a hardware exception due to a canary memory access; and instructions for causing the computer to declare a real-time fault condition if the hardware exception is due to the canary memory access being detected during the executing the software code.

In one example, the non-transitory computer-readable medium further includes instructions for causing the computer to execute a recovery procedure from the real-time fault condition; instructions for causing the computer to retrieve an original data from the main memory; instructions for causing the computer to send the original data to a compression module of a compression/decompression engine; instructions for causing the computer to execute data compression of the original data to generate a compressed data of a compressed size of M bits, wherein the original data has an original size of N bits such that N is greater than M; and instructions for causing the computer to store the compressed data in a compressed data sector of the main memory using the meta data index.

These and other aspects of the present disclosure will become more fully understood upon a review of the detailed description, which follows. Other aspects, features, and implementations of the present disclosure will become apparent to those of ordinary skill in the art, upon reviewing the following description of specific, exemplary implementations of the present invention in conjunction with the accompanying figures. While features of the present invention may be discussed relative to certain implementations and figures below, all implementations of the present invention can include one or more of the advantageous features discussed herein. In other words, while one or more implementations may be discussed as having certain advantageous features, one or more of such features may also be used in accordance with the various implementations of the invention discussed herein. In similar fashion, while exemplary implementations may be discussed below as device, system, or method implementations it should be understood that such exemplary implementations can be implemented in various devices, systems, and methods.

### BRIEF DESCRIPTION OF THE DRAWINGS

FIG. 1 illustrates an example information processing system.

FIG. 2 illustrates an example information processing system.

FIG. 3 illustrates a first example canary insertion architecture.

FIG. 4 illustrates a second example canary insertion architecture.

FIG. 5 illustrates a third example canary insertion architecture.

FIG. 6 illustrates an example flow diagram for data integrity detection.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

An information processing system, for example, a computing system with multiple slices (e.g., processing engines) or a system on a chip (SoC), may require multiple levels of coordination or synchronization. In one example, a slice includes a processing engine (i.e., a subset of the computing system) as well as associated memory units and other peripheral units. In one example, execution of an application may be decomposed into a plurality of work tasks which are executed by multiple slices or multiple processing engines.

In one example, the associated memory units of the information processing system may form a memory hierarchy with a local memory unit or an internal cache memory unit dedicated to each slice, a global memory unit shared among all slices and other memory units with various degrees of shared access. For example, a first level cache memory or L1 cache memory may be a memory unit dedicated to a single processing engine and may be optimized with a faster memory access time at the expense of storage space. For example, a second level cache memory or L2 cache memory may be a memory unit which is shared among more than one processing engine and may be optimized to provide a larger storage space at the expense of memory access time. In one example, each slice or each processing engine includes a dedicated internal cache memory.

In one example, the memory hierarchy may be organized as a cascade of cache memory units with the first level cache memory, the second level cache memory and other memory units with increasing storage space and slower memory access time going up the memory hierarchy. In one example, other cache memory units in the memory hierarchy may be introduced which are intermediate between existing memory units. For example, an L1.5 cache memory, which is intermediate between the L1 cache memory and the L2 cache memory, may be introduced in the memory hierarchy of the information processing system.

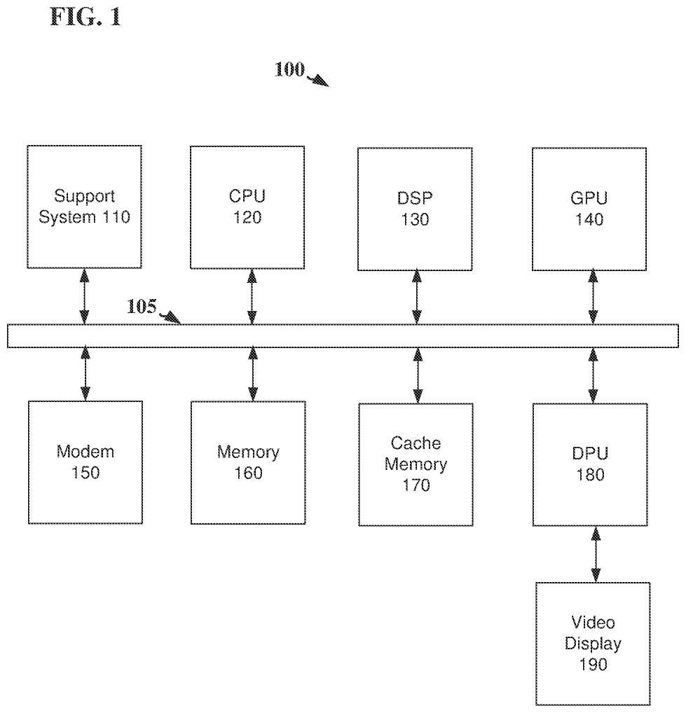

FIG. 1 illustrates an example information processing system 100. In one example, the information processing system 100 includes a plurality of processing engines such as a central processing unit (CPU) 120, a digital signal processor (DSP) 130, a graphics processing unit (GPU) 140, a display processing unit (DPU) 180, etc. In one example, various other functions in the information processing system 100 may be included such as a support system 110, a modem 150, a memory 160, a cache memory 170 and a video display 190. For example, the plurality of processing engines and various other functions may be interconnected by an interconnection databus 105 to transport data and control information.

In one example, the memory 160 and/or the cache memory 170 may be shared among the CPU 120, the GPU 140 and the other processing engines. In one example, the CPU 120 may include a first internal memory which is not shared with the other processing engines. In one example, the GPU 140 may include a second internal memory which is not shared with the other processing engines. In one example, any processing engine of the plurality of processing engines may have an internal memory (i.e., a dedicated memory) which is not shared with the other processing engines. Although several components of the information processing system 100 are included herein, one skilled in the art would understand that the components listed herein are examples and are not exclusive. Thus, other components may be included as part of the information processing system 100 within the spirit and scope of the present disclosure.

In one example, a memory unit in the information processing system 100, such as memory 160 and cache memory 170, may be a compressed memory unit. A compressed memory unit stores compressed data. In one example, compressed data is derived from original data after being processed by a compression module. In one example, decompressed data is derived from compressed data after being processed by a decompression module. In one example, the compression module is a module which accepts original data with an original size of N bits and produces compressed data with a compressed size of M bits, where M<N. For example, the decompression module may be a module which accepts compressed data with the compressed size of M bits and produces decompressed data with a decompressed size of P bits, where M<P. In one example, if the original data is identical to the decompressed data (and N=P), the compression module and decompression module are lossless modules. In one example, if the original data is not identical (e.g., but nearly identical) to the decompressed data, the compression module and decompression module are lossy modules.

In one example, the compressed memory unit may be used to reduce storage requirements of data in memory 160 or cache memory 170 by incorporating the compression module and the decompressing module. In one example, the compressed memory unit may be lossless or lossy. For example, the compressed memory unit may have a compression metric C which is equal to the ratio of original data over the compressed data (i.e., C=N/M). For example, if the original data has original size N=1 Mbit and the compressed data has compressed size M=100 kbit, the compression metric C=N/M=10.

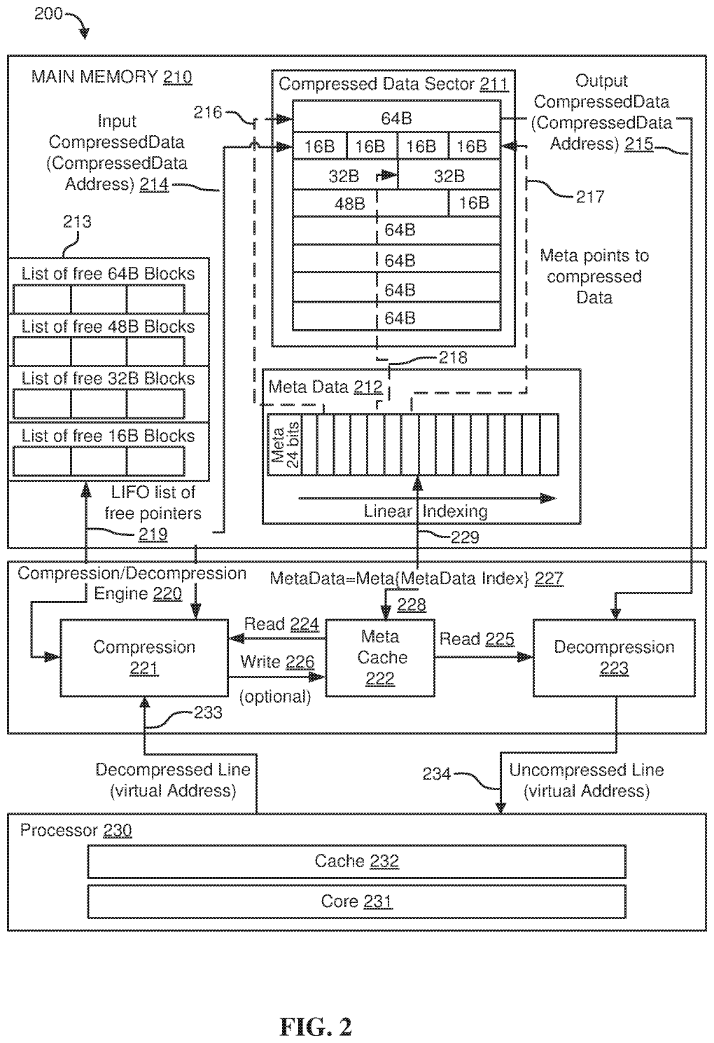

FIG. 2 illustrates an example information processing system 200. In one example, the information processing system 200 includes a main memory 210 (e.g., a double data rate (DDR) memory), a compression/decompression engine 220 and a processor 230. In one example, the compression/decompression engine 220 may reduce the amount of main memory 210 needed to store a group of data.

In one example, the main memory 210 includes a compressed data sector 211, meta data sector 212, a plurality of block lists 213, an input compressed data 214, an output compressed data 215, a first meta data pointer 216, a second meta data pointer 217, a third meta data pointer 218 and a last in first out (LIFO) list of free pointers 219. In one example, the input compressed data 214 is indexed by an input compressed data address. In one example, the output compressed data 215 is indexed by an output compressed data address.

In one example, compressed data sector 211 may be organized into a plurality of data words with a word size of Q bytes (i.e., one byte=8 bits). For example, the word size Q=64 bytes (B). For example, each data word of the plurality of data words may include data elements have an element size smaller than the word size Q (e.g., data elements with element size 16 B, 32 B, 48 B, etc.). In one example, the meta data sector 212 provides a mapping from a memory address to a location of the compressed data sector 211. For example, the meta data sector 212 may include a plurality of meta data words with meta data word size of 24 bits (i.e., 3 bytes). In one example, the memory address is a meta data index. In one example, the meta data sector 212 includes a designated memory location to serve as a data integrity mechanism used to detect a memory buffer overflow due to a security attack. In one example, the mechanism is a canary.

In one example, the compression/decompression engine 220 includes a compression module 221, a meta cache memory 222 and a decompression module 223. In one example, the compression module 221 uses the LIFO list of free pointers 219 to deliver the input compressed data 214 to the compressed data sector 211. In one example, the decompression module 223 retrieves the output compressed data 215 from the compressed data sector 211. In one example, the decompression module 223 retrieves the output compressed data 215 from the compressed data sector 211 to the decompression module 223.

In one example, the compression module 221 examines previous data in meta data sector 212, using the first meta data pointer 216. In one example, the compression module 221 determines if a compressed data block cannot be reused. In one example, the compressed data block may be recycled to an appropriate free list in the plurality of block lists 213. In one example, a new compressed data block of an appropriate size is allocated.

In one example, the decompression module 223 requires a lookup into meta data sector 212, using the second meta data pointer 217, to determine location of a compressed data block.

In one example, the meta cache memory 222 provides a first read data 224 to the compression module 221 and a second read data 225 to the decompression module 223. In one example, the compression module 221 may supply write data 226 to the meta cache memory 222. In one example, the first read data 224, the second read data 225 and the write data 226 are arbitrary data.

In one example, the compression/decompression engine 220 includes a meta data register 227 which provides a first meta input 228 to the meta cache memory 222 and a second meta input 229 to meta data sector 212. In one example, the meta data register 227 provides a linear map from original data to compressed data to determine location of the compressed data.

In one example, the processor 230 includes a core processor 231 and a cache memory 232. In one example, the processor 230 sends a decompressed line (e.g., decompressed virtual address) 233 to the compression module 221. In one example, the processor 230 receives an uncompressed line (e.g., uncompressed virtual address) 234 from the decompression module 223. In one example, the compression and decompression algorithms executed by the compression/decompression engine 220 may be lossless or lossy and may utilize any of a plurality of compression and decompression techniques.

In one example, a security attack by an attacker, such as fuzzing, may cause a memory buffer overflow. In one example, a memory buffer is a portion of memory, for example, the main memory 210, used for temporary data storage, with a valid meta data index range. In one example, a memory buffer overflow is an attempt to read or write data into the memory buffer outside of the valid meta data index range. In one example, a security attack is a malicious access or attempt to access resources of an information processing system.

In one example, fuzzing is an automated security attack which may expose security vulnerabilities by injecting random or extreme data as input to a target software program or utility. In one example, a canary is a data integrity mechanism used to detect a memory buffer overflow due to a security attack or a programming error. In one example, the canary may use an index or address label which points outside the valid meta data index range for compressed data area in the compressed data sector 211 of the main memory 210 to detect the memory buffer overflow.

In one example, a first example software code may have the following code:
int array[4]; declaration of 4 word (16 B)
void (*fptr) ( )=&bar; function pointer
void foo (int *input, int size)
{ memcpy (array, input, size); copy command
fptr ( ); }

In one example, the first example software code may have a security and stability issue if the parameter “size” is greater than 16 B (i.e., greater than 4 words) which overwrites “array” and “fptr”. That is, if invalid parameters are passed into function “foo”, an overwrite of the function pointer “fptr” may occur.

In one example, a second example software code, with an added canary, may have the following code:
int array[4]; declaration of 4 word (16 B)
int canary=0xDEADBEEF; added canary
void (*fptr) ( )=&bar; function pointer
void foo (int *input, int size)
{ memcpy (array, input, size); copy command
fptr ( ); }

In one example, the added canary may be checked periodically and with delay, and may also increase image size. In one example, an inserted canary detects an anomaly at a time of the anomaly, not some delayed time after the time of the anomaly. In one example, real-time refers to events which occur without perceptible or significant time delay. For example, if a physical process executes one event every event period, where the event period is 1 millisecond (i.e., at an event rate of 1000 events per second), the physical process is considered a real-time process if a real-time event implies initiation and completion of that event within the event period of 1 ms.

In one example, the compressed data sector 211 may be organized such that a data block with block size D (e.g., D=64 B) has a meta data index Idx with index size E (e.g., E=3 B=24 bits) which maps into a compressed data area in the compressed data sector 211. In one example, if a first inserted canary with block size D (e.g., D=64 B) is created at software build time, the meta data index Idx for the first inserted canary is mapped outside the valid meta data index range for the compressed data area in the compressed data sector 211. In one example, the creation of the first inserted canary may trigger a hardware exception (a.k.a., hardware fault) if the first canary is accessed.

In one example, a third example software code, with a first inserted canary created at software build time, may have the following code:
int array[4]; declaration of 4 word (16 B)
64B canary=CLADE2 (INVALID_IDX); cache line aligned (64 B)
void (*fptr) ( )=&bar; function pointer
void foo (int *input, int size)
{ memcpy (array, input, size); copy command
fptr ( ); }

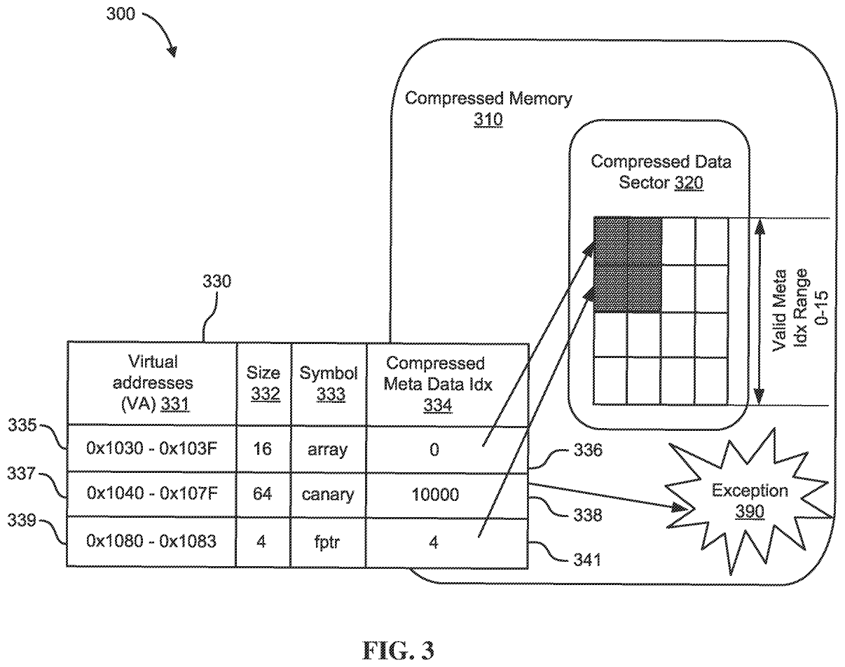

FIG. 3 illustrates a first example canary insertion architecture 300. In one example, a compressed memory subsystem 310 includes a compressed data sector 320 including a plurality of compressed data words. In one example, the compressed data sector 320 has a valid meta data index range of 16 words (e.g., Idx=0 to 15).

In one example, a meta data sector 330 includes a plurality of virtual addresses (VA) 331, a size 332, a symbol 333 and a meta data index Idx 334. In one example, the meta data index Idx 334 points to the plurality of compressed data words in the compressed data sector 320. For example, a first VA 335 (i.e., 0x1030 to 0x103F), associated with symbol “array”, has a first meta data index Idx 336 of 0, which is in the valid meta data index range. For example, a second VA 337 (i.e., 0x1040 to 0x107F), associated with symbol “canary”, has a second meta data index Idx 338 of 10000, which is not in the valid meta data index range. For example, a third VA 339 (i.e., 0x1080 to 0x1083), associated with symbol “fptr”, has a third meta data index Idx 341 of 4, which is in the valid meta data index range. In one example, the meta data sector 330 indicates an invalid meta data index.

In one example, the inserted canary created at software build time with meta data index not in the valid meta data index range may be used to trigger a hardware exception 390 if the inserted canary is accessed. In one example, the hardware exception is an exception to expected behavior during execution of a software code. In one example, the execution of software code means that the software code is running. In one example, the triggered hardware exception 390 may allow real-time detection of a memory buffer overflow. In one example, the triggered hardware exception 390 is detected by the processor 230. In one example, the processor 230 includes a fault protection circuit for detecting a fault condition. In one example, the fault condition is a software exception or the hardware exception 390. In one example, the detection of the hardware exception 390 is performed by the fault protection circuit (not shown) located in the core processor 231.

In one example, the compressed data sector 211 (of FIG. 2) may be organized with dynamic allocation on a stack memory and heap memory with a dynamic canary inserted after dynamically allocated arrays. In one example, the stack memory is a form of last in first out (LIFO) memory with a fixed memory size and with local variables. In one example, the heap memory is a random access memory which is dynamically allocated with an arbitrary memory size and with global variables.

In one example, two additional software instructions are needed at software build time to allow the software code to dynamically set and clear a specific meta data index to be invalid at software run time. In one example, the two additional software instructions are:
set_compressed_canary(VA)
clear_compressed_canary(VA)

For example, the first additional software instruction inserts a canary and the second additional software instruction removes the canary. In one example, a read access or write access to the dynamic canary will trigger a hardware exception.

In one example, a fourth example software code, with a second inserted canary, may have the following code:
void foo (int *input, int size)
{ int array[4]; declaration of 4 word (16 B)
64B canary=CLADE2 (INVALID_IDX); cache line aligned (64 B)
void (*fptr) ( )=&bar; function pointer
   memcpy (array, input, size); copy command
fptr ( ); }

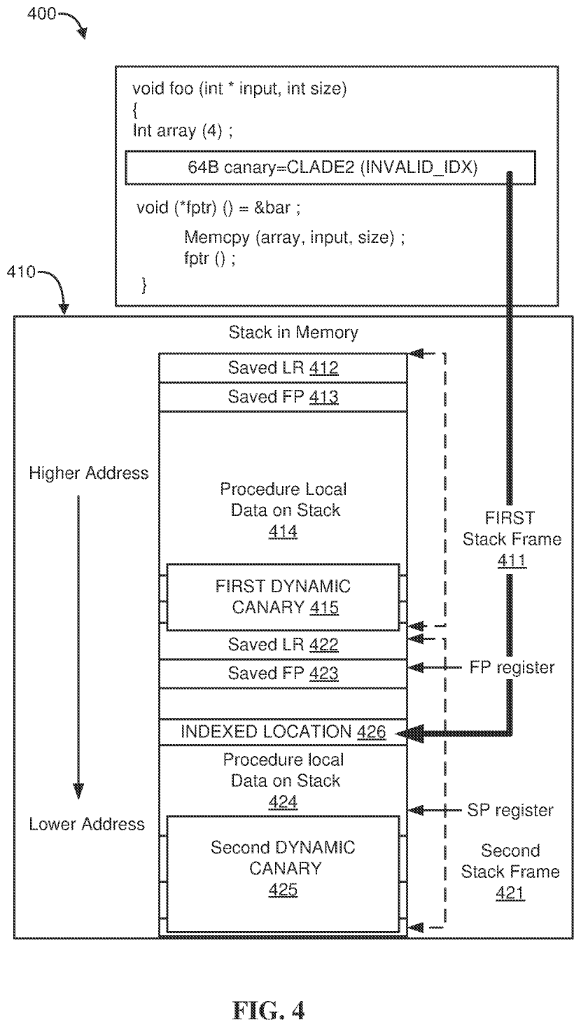

FIG. 4 illustrates a second example canary insertion architecture 400. In one example, a memory 410 may be organized with higher addresses at the top and lower addresses at the bottom of the memory 410. In one example, a first stack frame 411 is a group of data in the memory 410 with higher addresses. For example, a link register in the first stack frame 411 may store a return address for a function call. For example, a frame register in the first stack frame 411 may hold an address to a last word of the first stack frame 411. In one example, the first stack frame 411 may include a first saved link register (LR) 412, a first saved frame register (FR) 413, a first procedure local data 414 and a first dynamic canary 415.

In one example, the memory 410 may also include a second stack frame 421 with a second saved LR 422, a second saved FR 423, a second procedure local data 424 and a second dynamic canary 425. In one example, the memory 410 may also include an indexed location 426 to store an address for the function call.

In one example, the compressed data sector 211 (of FIG. 2) may be organized to avoid a “use after free” error. In one example, memory allocated on a stack memory or a heap memory may be subject to memory usage issues after the memory has been deallocated or released.

In one example, a fifth example software code may have the following code:
int *temp //create a pointer to an integer
temp=malloc (sizeof (int)); //allocate memory
*temp=0; //store zero on the heap
free(temp) //release the memory back
*temp=0; //incorrectly use the pointer

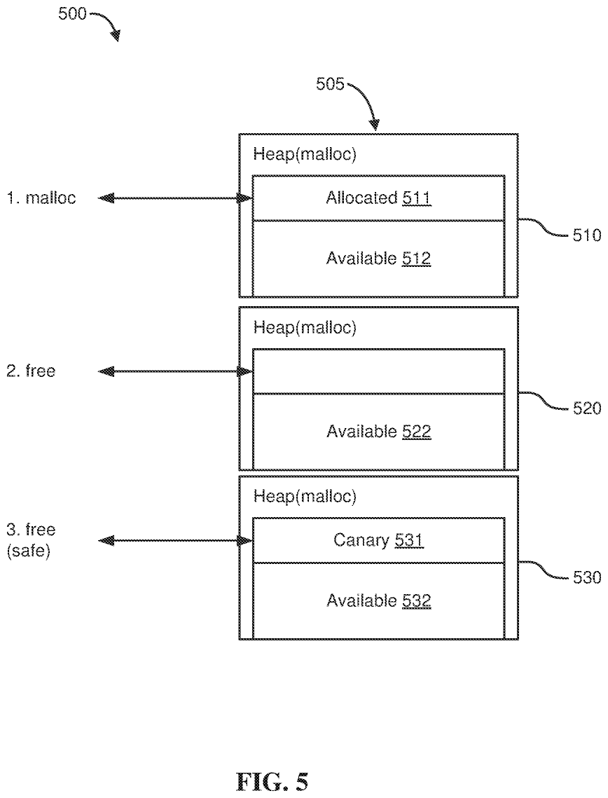

FIG. 5 illustrates a third example canary insertion architecture 500. In one example, a memory 505 may be organized as a first heap sector 510 after allocation, a second heap sector 520 after deallocation and a third heap sector 530 after canary insertion. In one example, the first heap sector 510, the second heap sector 520 and the third heap sector 530 are the same physical memory area of the memory 505, but at different times and after different operations.

In one example, the first heap sector 510 after allocation uses the “malloc” operation to set aside an allocated memory area 511 in the first heap sector 510 which results in a first available memory area 512 in the first heap sector 510.

In one example, the second heap sector 520 after deallocation uses the “free” operation to set free a previously allocated memory area in the second heap sector 520 which results in a second available memory area 522 in the second heap sector 520. For example, the second available memory area 522 in the second heap sector 520 is equivalent to a combination of the allocated memory area 511 and the first available memory area 512 in the first heap sector 510.

In one example, the third heap sector 530 after deallocation uses the free operation to set free a previously allocated memory area in the third heap sector 530 which may result in a third available memory area 532 in the third heap sector 530. In one example, a canary 531 may be inserted at a location of the previously allocated memory area.

In one example, the previously allocated memory area of the second available memory 522 may still be accessed by faulty software code. In one example, as a mitigation, a canary may be inserted at a location of the previously allocated memory location using an instruction:
set_compressed_canary(VA)

In one example, any subsequent or superfluous access to the area of the inserted canary may result in a hardware exception. In one example, the inserted canary may be removed at a later time using an instruction:
clear_compressed_canary(VA)

In one example, the previously allocated memory area may be reclaimed for use by the memory 505.

In one example, the compressed data sector 211 (of FIG. 2) may be organized to detect a memory read operation prior to an initial memory write operation. In one example, a canary may be inserted using an instruction:
set_compressed_canary_w_not_r(VA)

In one example, a sixth example software code may have the following code:
set_compressed_canary_w_not_r(VA)pl
meta_data_Idx[0]=“−2”

In one example, if the next operation of the sixth example software code is a read operation of the associated VA, the compression module may detect an index equal to −2 and raises a hardware exception. In one example, if the next operation of the sixth example software code is a write operation of the associated VA, the compression module may detect an index equal to −2 and continues nominal operations.

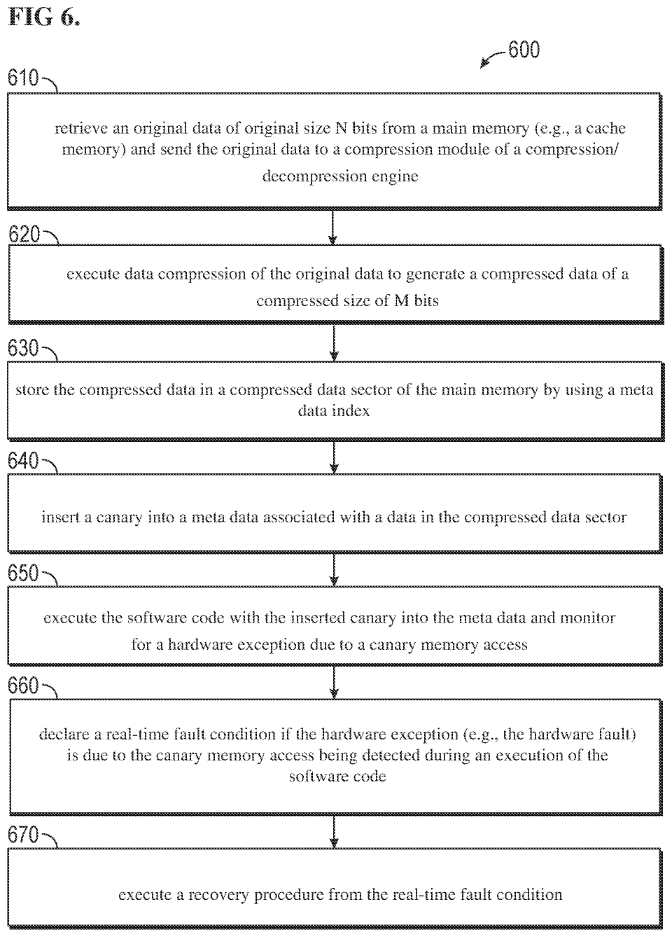

FIG. 6 illustrates an example flow diagram 600 for data integrity detection. In one example, the flow diagram 600 may be used for detecting a memory buffer overflow using inserted canaries in software code. In block 610, retrieve an original data of original size N bits from a main memory (e.g., a cache memory) and send the original data to a compression module of a compression/decompression engine. That is, an original data of original size N bits is retrieved from a main memory and sent to a compression module of a compression/decompression engine.

In block 620, execute data compression of the original data to generate a compressed data of a compressed size of M bits. That is, the original data is data compressed to generate a compressed data of a compressed size of M bits. In one example, M<N. In one example, a compression metric C=N/M is greater than unity. In one example, the data compression may be lossless. In one example, the data compression may be lossy.

In block 630, store the compressed data in a compressed data sector of the main memory by using a meta data index. That is, the compressed data is stored in a compressed data sector of the main memory by using a meta data index. In one example, the meta data index has a valid meta data index range to determine a memory buffer overflow. In one example, the memory buffer overflow is an attempt to read or write data into the memory buffer outside of the valid meta data index range. In one example, the meta data index may be used to map a memory virtual address (VA) to the compressed data sector of the main memory.

In block 640, insert a canary into a meta data associated with a data in the compressed data sector. That is, a canary is inserted into a meta data associated with a data in the compressed data sector. In one example, the canary has the meta data index which has an invalid value. In one example, the canary has a meta data index which is outside the valid meta data index range. In one example, the canary has a canary virtual address (VA). In one example, the inserted canary is created at a software build time. In one example, the canary uses an index or address label which points outside the valid meta data index range for a compressed data area in the compressed data sector 211. In one example, the inserted canary detects a memory buffer overflow. In one example, the compressed data area has a static memory allocation in main memory 210.

In one example, the inserted canary is generated in the compressed data sector. In one example, the compressed data sector has a dynamic memory allocation. In one example, the inserted canary is placed (i.e., stored) after the compressed data sector has been dynamically allocated. In one example, the inserted canary is dynamically generated at a software run time. In one example, the inserted canary is dynamically cleared at the software run time. In one example, the dynamic memory allocation is on a stack memory. In one example, the dynamic memory allocation is on a heap memory. In one example, the stack memory is a form of last in first out (LIFO) memory with a fixed memory size and with local variables. In one example, the heap memory is a random-access memory (RAM) which is dynamically allocated with an arbitrary memory size and with global variables.

In one example, the inserted canary is inserted at a location of a previously allocated memory area. In one example, the previously allocated memory area is set free using a free operation. In one example, the previously allocated memory area is on a stack memory. In one example, the previously allocated memory area is on a heap memory. In one example, the previously allocated memory area is on a heap sector.

In one example, the inserted canary is inserted to detect a memory read operation prior to an initial memory write operation. In one example, the inserted canary may have a specified meta data index value used to detect a subsequent read operation. In one example, a fault is detected if a subsequent read operation occurs, and a fault is not detected if a subsequent write operation occurs.

In block 650, execute the software code with the inserted canary into the meta data and monitor for a hardware exception due to a canary memory access. That is, the software code is executed with the inserted canary into the meta data and monitored for a hardware exception due to a canary memory access. In one example, a canary memory access is an access to the canary in memory (e.g., the main memory 210). In one example, access is a read operation or a write operation to the memory (e.g., the main memory 210).

In block 660, declare a real-time fault condition if the hardware exception is due to the canary memory access being detected during an execution of a software code. That is, a real-time fault condition is declared if the hardware exception is due to the canary memory access being detected during an execution of a software code. In one example, a real-time fault condition refers to fault condition which occur without perceptible or significant time delay. In one example, a fault condition refers to a condition that is not an expected behavior.

In block 670, execute a recovery procedure from the real-time fault condition. That is, a recovery procedure is executed from the real-time fault condition. In one example, the recovery procedure prevents a memory buffer overwrite condition.

In one aspect, one or more of the steps for providing data integrity detection for information processing systems in FIG. 6 may be executed by one or more processors which may include hardware, software, firmware, etc. The one or more processors, for example, may be used to execute software or firmware needed to perform the steps in the flow diagram of FIG. 6. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

The software may reside on a computer-readable medium. The computer-readable medium may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium may reside in a processing system, external to the processing system, or distributed across multiple entities including the processing system. The computer-readable medium may be embodied in a computer program product. By way of example, a computer program product may include a computer-readable medium in packaging materials. The computer-readable medium may include software or firmware. Those skilled in the art will recognize how best to implement the described functionality presented throughout this disclosure depending on the particular application and the overall design constraints imposed on the overall system.

Any circuitry included in the processor(s) is merely provided as an example, and other means for carrying out the described functions may be included within various aspects of the present disclosure, including but not limited to the instructions stored in the computer-readable medium, or any other suitable apparatus or means described herein, and utilizing, for example, the processes and/or algorithms described herein in relation to the example flow diagram.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another-even if they do not directly physically touch each other. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

One skilled in the art would understand that various features of different embodiments may be combined or modified and still be within the spirit and scope of the present disclosure.

What is claimed is:

1. An apparatus for data integrity detection, the apparatus comprising:
a compressed data sector configured to store a compressed data;
a meta data sector coupled to the compressed data sector, the meta data sector configured to indicate an invalid meta data index; and
a compression/decompression engine coupled to the meta data sector, the compression/decompression engine configured to compress an original data to generate the compressed data and further configured to decompress the compressed data to generate a decompressed data.

2. The apparatus of claim 1, wherein the decompressed data is not the original data.

3. The apparatus of claim 1, further comprising a canary, wherein the canary is a designated memory location in the meta data sector, the canary configured to detect a memory buffer overflow due to a security attack or a programming error.

4. The apparatus of claim 3, further comprising a processor coupled to compression/decompression engine, the processor configured to detect a fault condition.

5. The apparatus of claim 4, further comprising a fault protection circuit located in a core processor of the processor, the fault protection circuit configured to detect the fault condition.

6. The apparatus of claim 5, wherein the fault condition is a hardware exception.

7. A method for implementing data integrity detection, the method comprising:
inserting a canary into a meta data associated with a data in a compressed data sector, wherein the inserting uses a meta data index;
executing the software code with an inserted canary into the meta data;
monitoring for a hardware exception due to a canary memory access; and
declaring a real-time fault condition if the hardware exception is due to the canary memory access being detected during the executing the software code.

8. The method of claim 7, further comprising executing a recovery procedure from the real-time fault condition.

9. The method of claim 8, further comprising retrieving an original data from the main memory and sending the original data to a compression module of a compression/decompression engine.

10. The method of claim 9, further comprising executing data compression of the original data to generate a compressed data of a compressed size of M bits.

11. The method of claim 10, wherein the original data has an original size of N bits such that N is greater than M.

12. The method of claim 10, further comprising storing the compressed data in a compressed data sector of the main memory using the meta data index.

13. The method of claim 12, further comprising generating the inserted canary in the compressed data sector.

14. The method of claim 13, wherein the inserted canary is stored after the compressed data sector is dynamically allocated.

15. The method of claim 14, wherein the compressed data sector is dynamically allocated on a stack memory.

16. The method of claim 14, wherein the compressed data sector is dynamically allocated on a heap memory.

17. The method of claim 7, wherein the meta data index includes an invalid value.

18. The method of claim 7, wherein the meta data index is outside a valid meta data index range.

19. The method of claim 18, wherein the canary includes a canary virtual address.

20. The method of claim 19, wherein the canary uses an address label which points outside a valid meta data index range for a compressed data area.

21. The method of claim 7, wherein the inserted canary is inserted at a location of a previously allocated memory area.

22. The method of claim 7, wherein the meta data index includes a valid meta data index range for determining a memory buffer overflow.

23. An apparatus for data integrity detection, the apparatus comprising:
means for inserting a canary into a meta data associated with a data in a compressed data sector;
means for executing the software code with an inserted canary into the meta data;
means for monitoring for a hardware exception due to a canary memory access; and
means for declaring a real-time fault condition if the hardware exception is due to the canary memory access being detected during the executing the software code.

24. The apparatus of claim 23, further comprising means for executing a recovery procedure from the real-time fault condition.

25. The apparatus of claim 24, further comprising means for storing a compressed data in a compressed data sector of the main memory using the meta data index.

26. The apparatus of claim 25, wherein the inserted canary is stored after the compressed data sector is dynamically allocated.

27. The apparatus of claim 26, wherein the meta data index includes an invalid value, or wherein the meta data index is outside a valid meta data index range.

28. The apparatus of claim 23, wherein the inserted canary is inserted at a location of a previously allocated memory area.

29. A non-transitory computer-readable medium storing computer executable code, operable on a device comprising at least one processor and at least one memory coupled to the at least one processor, wherein the at least one processor is configured to implement data integrity detection, the computer executable code comprising:
instructions for causing a computer to insert a canary into a meta data associated with a data in a compressed data sector;
instructions for causing the computer to execute the software code with an inserted canary into the meta data;
instructions for causing the computer to monitor for a hardware exception due to a canary memory access; and
instructions for causing the computer to declare a real-time fault condition if the hardware exception is due to the canary memory access being detected during the executing the software code.

30. The non-transitory computer-readable medium of claim 29, further comprising:
instructions for causing the computer to execute a recovery procedure from the real-time fault condition;
instructions for causing the computer to retrieve an original data from the main memory;
instructions for causing the computer to send the original data to a compression module of a compression/decompression engine;
instructions for causing the computer to execute data compression of the original data to generate a compressed data of a compressed size of M bits, wherein the original data has an original size of N bits such that N is greater than M; and
instructions for causing the computer to store the compressed data in a compressed data sector of the main memory using the meta data index.
